(19) United States
(12) Patent Application Publication
(10) Pub. No.: US 2026/0262531 A1
(43) Pub. Date: Sep. 3, 2026

(54) METHOD FOR MANUFACTURING SEMICONDUCTOR DEVICE, AND SEMICONDUCTOR DEVICE

(71) Applicant: Resonac Corporation, Minato-ku, Tokyo (JP)

(72) Inventors: Masaya TOBA, Minato-ku, Tokyo (JP); Kazuyuki MITSUKURA, Minato-ku, Tokyo (JP); Hirokazu NOMA, Minato-ku, Tokyo (JP)

(21) Appl. No.: 18/841,683

(22) PCT Filed: Feb. 22, 2023
(86) PCT No.: PCT/JP2023/006566

§ 371 Date: Oct. 4, 2024

(30) Foreign Application Priority Data
Feb. 28, 2022 (WO) PCT/JP2022/008405

(51) Int. Cl. H10W 72/90; H10W 72/00; H10W 90/00; H10W 90/26

(52) U.S. Cl. CPC H10W 72/9232; H10W 72/01935; H10W 72/01953; H10W 90/26; H10W 90/792

(57) ABSTRACT

A method for manufacturing a semiconductor device includes, preparing a first substrate having a first support substrate, a first insulating film, and a first electrode; preparing a second substrate having a second support substrate, a second insulating film, and a second electrode; bonding the first insulating film and the second insulating film to each other; and bonding the first electrode and the second electrode to each other. The first insulating film includes an organic insulating film. The first electrode includes a first electrode body in a first recess, a first barrier metal on at least one of an inner surface and a bottom surface of the first recess to cover a part of the first electrode body, and a second barrier metal covering a surface of the first electrode body. The bonding strength between the first insulating film and the first barrier metal is 30 MPa or more.

### TECHNICAL FIELD

The present disclosure relates to a method for manufacturing a semiconductor device, and a semiconductor device.

### BACKGROUND ART

In recent years, three-dimensional mounting has been studied in order to improve the degree of integration of LSIs. Patent Literature 1 and Non Patent Literature 1 disclose an example of three-dimensional mounting of semiconductor chips.

### CITATION LIST

### Patent Literature

Patent Literature 1: Specification of U.S. Patent Application Publication No. 2021/002815

### Non Patent Literature

Non Patent Literature 1: F. C. Chen et al., “System on Integrated Chips (SoIC™) for 3D Heterogeneous Integration”, 2019 IEEE 69th Electronic Components and Technology Conference (ECTC), p. 594-599 (2019)

### SUMMARY OF INVENTION

### Technical Problem

When manufacturing semiconductor devices using three-dimensional mounting, the use of hybrid bonding technology has been studied for miniaturization of the wiring between devices. However, as shown in FIG. 7B, when hybrid bonding is performed, a slight misalignment S may occur in the bonding between terminal electrodes (a first electrode 113 and a second electrode 123). Such a misalignment S occurs due to, for example, miniaturization of the terminal electrodes themselves, or due to differences in thermal expansion coefficients caused by heating during bonding. If such a misalignment S occurs in a semiconductor device, copper or the like forming the terminal electrodes may dissolve into the resin forming insulating films (a first insulating film 112 and a second insulating film 122), which may cause migration at the interface between the electrode formed of copper or the like and the insulating film.

It is an object of the present disclosure to provide a method for manufacturing a semiconductor device and a semiconductor device capable of decreasing migration at the interface between an electrode and an insulating film.

### Solution to Problem

[1] One aspect of the present disclosure relates to a method for manufacturing a semiconductor device. The method for manufacturing a semiconductor device includes: a) preparing a first substrate including a first support substrate, a first insulating film provided on the first support substrate, and a first electrode provided in a first recess of the first insulating film and exposed from a first surface side of the first insulating film, b) preparing a second substrate including a second support substrate, a second insulating film provided on the second support substrate, and a second electrode provided in a second recess of the second insulating film and exposed from a second surface side of the second insulating film, c) bonding the first insulating film of the first substrate and the second insulating film of the second substrate to each other, and d) bonding the first electrode of the first substrate and the second electrode of the second substrate to each other. The first insulating film includes an organic insulating film. The first electrode includes a first electrode body provided in the first recess, a first barrier metal provided on at least one of an inner surface and a bottom surface of the first recess to cover a part of the first electrode body, and a second barrier metal covering a surface of the first electrode body on an opening side of the first recess. A bonding strength between the first insulating film and the first barrier metal is 30 MPa or more.

In this method for manufacturing a semiconductor device, the first electrode provided on the first insulating film includes the first barrier metal covering a part of the first electrode body and a second barrier metal covering the surface of the first electrode body on the opening side of the first recess. In this case, the dissolution of the first electrode body, which is often formed of a material that dissolves easily, such as copper, is prevented by the first barrier metal and the second barrier metal. Therefore, even if a misalignment occurs between the first electrode and the second electrode at any stage, migration at the interface between the first electrode and the first insulating film can be prevented. The misalignment referred to herein includes even very small misalignments, so long as they may cause migration. The same applies hereinafter. The bond between an electrode material, such as copper, and a resin forming an insulating film (organic insulating film) may be weak to peel off. However, the first barrier metal is provided on at least one of the inner surface and the bottom surface of the first recess of the first insulating film to cover a part of the first electrode body, and the bonding strength between the first insulating film and the first barrier metal is 30 MPa or more, so that it is possible to prevent such peeling.

In this method for manufacturing a semiconductor device, the first insulating film includes an organic insulating film. In this case, an organic material, which is a relatively soft material, can absorb foreign matter (debris) adhering to the surface of the first substrate into the insulating film, thereby reducing poor connections between the first substrate and the second substrate. The organic insulating material contained in the insulating film may be polyimide, a polyimide precursor, polyamide-imide, benzocyclobutene (BCB), polybenzoxazole (PBO), or a PBO precursor. Since these materials are in a liquid state or soluble in a solvent, the insulating film can be easily manufactured by, for example, spin coating. Therefore, a thin film can be easily formed. Since these materials have high heat resistance, these materials can withstand high temperatures when bonding the first substrate and the second substrate to each other. Therefore, the first substrate and the second substrate can be more reliably bonded to each other. A part of the first insulating film can be formed as an inorganic insulating film, and the other part (for example, the front surface side) can be formed as an organic insulating film.
[2] In the method for manufacturing a semiconductor device according to [1] above, it is further preferable that the bonding strength between the first insulating film and the first barrier metal is 40 MPa or more. In this case, peeling between the electrode body formed of copper or the like and the organic insulating film can be further prevented by the first barrier metal. The bonding strength between the first insulating film and the first barrier metal may be 50 MPa or more.
[3] In the method for manufacturing a semiconductor device described above, a) the preparing of the first substrate includes: a1) forming the first insulating film on the first support substrate, a2) forming at least the one first recess in the first insulating film, a3) forming the first barrier metal on the inner surface and the bottom surface of the first recess, a4) forming the first electrode body in a region surrounded by the first barrier metal within the first recess, and a5) forming a second barrier metal on the surface of the first electrode body. In addition, b) the preparing of second substrate includes: b1) forming the second insulating film on the second support substrate, b2) forming at least the one second recess in the second insulating film, b3) forming the third barrier metal on the inner surface and the bottom surface of the second recess, b4) forming the second electrode body in a region surrounded by the third barrier metal within the second recess, and b5) forming a fourth barrier metal on the surface of the second electrode body.
[4] In the method for manufacturing a semiconductor device according to [3] above, in the forming of the first barrier metal, the first barrier metal may be formed in the first recess of the first insulating film by electroless plating. In this case, the bonding strength between the first insulating film and the first barrier metal can be easily increased.

[5] In the method for manufacturing a semiconductor device according to [4] above, in the forming of the first electrode body, the first electrode body may be formed by electrolytic plating using the first barrier metal as a power supply layer. In this case, the bonding strength between the first barrier metal and the first electrode body can also be increased.
[6] In the method for manufacturing a semiconductor device according to any one of [3] to [5] above, in a4) the forming of the first electrode body, a conductive material may be arranged on the first insulating film and the first barrier metal in the first recess so as to fill the first recess, and the arranged conductive material may be ground to form the first electrode body. In addition, in b4) the forming of the second electrode body, a conductive material may be arranged on the second insulating film and the third barrier metal in the second recess so as to fill the second recess, and the arranged conductive material may be ground to form the second electrode body.
[7] In the method for manufacturing a semiconductor device according to [6] above, in a4) the forming of the first electrode body, the first insulating film may be polished after the conductive material is ground, and in b4) the forming of the second electrode body, the second insulating film may be further polished after the conductive material is ground. A surface roughness of each of the polished first insulating film and second insulating film may be 0.1 μm or less. By setting the surface roughness of each of the first insulating film and the second insulating film 0.1 μm or less, it is possible to increase the bonding strength when the first insulating film and the second insulating film are bonded to each other. The surface roughness used herein is an arithmetic mean roughness Ra measured using a laser microscope at a magnification of 20 times, and is the arithmetic mean roughness Ra specified in JIS B 0601 2001.
[8] In the method for manufacturing a semiconductor device according to [6] or [7] above, in a5) the forming of the second barrier metal, the second barrier metal may be formed so as to cover the surface of the first electrode body after the conductive material is ground, and in b5) the forming of the fourth barrier metal, the fourth barrier metal may be formed so as to cover the surface of the second electrode body after the conductive material is ground. In this case, it is possible to increase the bonding strength between the first electrode body and the second barrier metal and the bonding strength between the second electrode body and the fourth barrier metal.
[9] In the method for manufacturing a semiconductor device according to any one of [3] to [8] above, a) the preparing of the first substrate may include modifying the surface of the first electrode body using at least one method of ultraviolet irradiation, electron beam irradiation, ozone water treatment, corona discharge treatment, and plasma treatment before the forming of the second barrier metal. In this case, since it is possible to improve the bonding strength of the second barrier metal with respect to the first electrode body, it is possible to prevent migration by preventing the peeling of the second barrier metal and the like. In b) the preparing of the second substrate, the surface of the second electrode body may be subjected to a similar treatment.
[10] In the method for manufacturing a semiconductor device according to any one of [1] to [9] above, it is preferable that the first electrode body is entirely covered with the first barrier metal and the second barrier metal. In this case, migration at the interface between the first electrode and the first insulating film can be more reliably prevented. It is preferable that the second electrode body is entirely covered with the third barrier metal and the fourth barrier metal. In this case, migration at the interface between the second electrode and the second insulating film can be more reliably prevented.
[11] In the method for manufacturing a semiconductor device according to any one of [1] to [10] above, a thickness of the second barrier metal before bonding the first electrode and the second electrode to each other may be 1 μm or less, and a thickness of the fourth barrier metal before bonding the first electrode and the second electrode to each other may be 1 μm or less. In this case, the terminal electrodes can be made finer more reliably.
[12] In the method for manufacturing a semiconductor device according to any one of [1] to [11] above, the second insulating film may include an organic insulating film, and the second electrode may include a second electrode body provided in the second recess, a third barrier metal provided on at least one of an inner surface and a bottom surface of the second recess to cover a part of the second electrode body, and a fourth barrier metal covering a surface of the second electrode body on an opening side of the second recess. In this manufacturing method, it is preferable that a bonding strength between the second insulating film and the third barrier metal is 30 MPa or more. In this case, the dissolution of the second electrode body, which is often formed of a material that dissolves easily, such as copper, is prevented by the third barrier metal and the fourth barrier metal. Therefore, even if a misalignment occurs between the first electrode and the second electrode at any stage, migration at the interface between the second electrode and the second insulating film can be prevented. The bond between an electrode material, such as copper, and a resin forming an insulating film (organic insulating film) may be weak to peel off. However, the third barrier metal is provided on at least one of the inner surface and the bottom surface of the second recess of the second insulating film to cover a part of the second electrode body, and the bonding strength between the second insulating film and the third barrier metal is 30 MPa or more, so that it is possible to prevent such peeling. Since the second insulating film contains an organic insulating film, it is possible to reduce poor connections by absorbing foreign matter, similarly to the above case of the first insulating film. The bonding strength between the second insulating film and the third barrier metal may be 40 MPa or more, or may be 50 MPa or more.
[13] In the method for manufacturing a semiconductor device according to [12] above, the first electrode may be formed so that a surface of the second barrier metal is recessed inward from the first surface of the first insulating film, and the second electrode may be formed so that a surface of the fourth barrier metal protrudes outward from the second surface of the second insulating film. In this case, it is preferable that, in c) the bonding of the first insulating film and the second insulating film to each other, a protruding part of the fourth barrier metal is fitted into a recessed region of the second barrier metal. Due to such an uneven configuration, the first substrate and the second substrate are more reliably aligned to prevent misalignment. As a result, it is possible to further prevent migration at the interface between the electrode and the insulating film.
[14] In the method for manufacturing a semiconductor device according to any one of [1] to [13] above, at least one semiconductor element may be arranged within the first support substrate or on a surface of the first support substrate opposite to a surface on which the first insulating film is formed. At least one semiconductor element may be arranged within the second support substrate or on a surface of the second support substrate opposite to a surface on which the second insulating film is formed.
[15] In the method for manufacturing a semiconductor device according to any one of [1] to [14] above, when bonding the first electrode and the second electrode to each other, the second barrier metal and the fourth barrier metal may be bonded to each other. In this case, even if a misalignment occurs between the first electrode and the second electrode, a part of at least one of the second barrier metal and the fourth barrier metal is bonded to the resin, thereby preventing the first electrode body and the second electrode body from being bonded to the resin. Therefore, it is possible to more reliably prevent migration at the interface between the first electrode and the first insulating film and at the interface between the second electrode and the second insulating film.
[16] In the method for manufacturing a semiconductor device according to any one of [1] to [15] above, it is preferable that the second barrier metal and the fourth barrier metal contain at least one selected from titanium, nickel, palladium, chromium, tantalum, tungsten, cobalt, and gold. More preferably, the second barrier metal and the fourth barrier metal contain at least one selected from nickel, cobalt, and tungsten. These materials have a low ionization tendency and accordingly, have a high barrier performance. Since the second barrier metal and the fourth barrier metal contain such a material with high barrier performance, migration at the interface between the first electrode and the first insulating film and at the interface between the second electrode and the second insulating film can be more reliably prevented.
[17] In the method for manufacturing a semiconductor device according to any one of [1] to [16] above, it is preferable that the first recess and the second recess have an opening diameter or an opening width of 5 μm to 50 μm. According to this method for manufacturing a semiconductor device, it is possible to prevent migration even when a terminal electrode or a wiring electrode is formed in such a fine recess, so that it is possible to manufacture a semiconductor device having fine wiring.
[18] In the method for manufacturing a semiconductor device according to any one of [1] to [17] above, at least one of the first insulating film and the second insulating film may partially include an inorganic insulating film. When the insulating film includes an inorganic insulating film, recesses for forming terminal electrodes and the like can be easily made finer. Therefore, it is possible to manufacture a semiconductor device having finer wiring. Since it is easy to strengthen the bonding between inorganic materials, it is possible to improve the connection reliability of the semiconductor device by increasing the bonding strength between the first substrate and the second substrate.
[19] In the method for manufacturing a semiconductor device according to any one of [1] to [18] above, the second barrier metal and the fourth barrier metal may be formed by plating. In this case, a thinner and finer barrier metal can be easily manufactured.
[20] Another aspect of the present disclosure relates to a semiconductor device. The semiconductor device includes a first substrate and a second substrate. The first substrate includes a first support substrate, a first insulating film provided on the first support substrate, and a first electrode provided in a first recess of the first insulating film and exposed from a first surface side of the first insulating film. The second substrate includes a second support substrate, a second insulating film provided on the second support substrate, and a second electrode provided in a second recess of the second insulating film and exposed from a second surface side of the second insulating film. In this semiconductor device, the first insulating film includes an organic insulating film, the first insulating film and the second insulating film are bonded to each other, and the first electrode and the second electrode are bonded to each other. The first electrode includes a first electrode body provided in the first recess, a first barrier metal provided on at least one of an inner surface and a bottom surface of the first recess to cover a part of the first electrode body, and a second barrier metal covering a surface of the first electrode body on an opening side of the first recess. The bonding strength between the first insulating film and the first barrier metal is 30 MPa or more.

In this semiconductor device, the first electrode provided on the first insulating film have the first barrier metal covering a part of the first electrode body and the second barrier metal covering the surface of the first electrode body on the opening side of the first recess. In this case, the dissolution of the first electrode body, which is often formed of a material that dissolves easily, such as copper, is prevented by the first barrier metal and the second barrier metal. Therefore, it is possible to prevent migration at the interface between the first electrode and the first insulating film. The bond between an electrode material, such as copper, and a resin forming an insulating film (organic insulating film) may be weak to peel off. However, the first barrier metal is provided on at least one of the inner surface and the bottom surface of the first recess of the first insulating film to cover a part of the first electrode body, and the bonding strength between the first insulating film and the first barrier metal is 30 MPa or more, so that it is possible to prevent such peeling. The bonding strength between the first insulating film and the first barrier metal may be 40 MPa or more, or may be 50 MPa or more.

In the semiconductor device described above, the second insulating film may include an organic insulating film, and the second electrode may include a second electrode body provided in the second recess, a third barrier metal provided on at least one of an inner surface and a bottom surface of the second recess to cover a part of the second electrode body, and a fourth barrier metal covering a surface of the second electrode body on an opening side of the second recess. A bonding strength between the second insulating film and the third barrier metal is 30 MPa or more. In this case, the dissolution of the second electrode body, which is often formed of a material that dissolves easily, such as copper, is prevented by the third barrier metal and the fourth barrier metal. Therefore, it is possible to prevent migration at the interface between the second electrode and the second insulating film. The bond between an electrode material, such as copper, and a resin forming an insulating film (organic insulating film) may be weak to peel off. However, the third barrier metal is provided on at least one of the inner surface and the bottom surface of the second recess of the second insulating film to cover a part of the second electrode body, and the bonding strength between the second insulating film and the third barrier metal is 30 MPa or more, so that it is possible to prevent such peeling. The bonding strength between the second insulating film and the third barrier metal may be 40 MPa or more, or may be 50 MPa or more.

### Advantageous Effects of Invention

According to the present disclosure, it is possible to prevent migration at the interface between an electrode and an insulating film.

### BRIEF DESCRIPTION OF DRAWINGS

FIG. 1 is a cross-sectional view showing an example of a semiconductor device manufactured by using a method according to an embodiment of the present disclosure.

FIG. 2 is an enlarged cross-sectional view showing a bonding portion A between electrodes in the semiconductor device shown in FIG. 1.

FIGS. 3A to 3D are cross-sectional views for describing a method for manufacturing the semiconductor device shown in FIG. 1, and shows an example of a process of manufacturing a first substrate and a second substrate.

FIG. 4 is an enlarged cross-sectional view showing a region B shown in FIG. 3D.

FIGS. 5A and 5B are cross-sectional views for describing the method for manufacturing the semiconductor device shown in FIG. 1, and shows an example of a process of bonding the first substrate and the second substrate to each other, subsequent to the process in FIGS. 3A to 3D.

FIGS. 6A and 6B are cross-sectional views showing an example when a misalignment occurs in the process shown in FIGS. 5A and 5B.

FIG. 7A is a cross-sectional view showing a case where a misalignment occurs at a bonding portion of a semiconductor device manufactured by using the method according to the present embodiment, and FIG. 7B is a cross-sectional view showing a case where a misalignment occurs at a bonding portion of a semiconductor device manufactured by using a method according to a comparative example.

FIGS. 8A and 8B are cross-sectional views for describing a first modification example of the semiconductor device manufacturing method according to the present embodiment, where FIG. 8A is a cross-sectional view before bonding electrodes to each other and FIG. 8B is a cross-sectional view after bonding the electrodes to each other.

FIG. 9 is a cross-sectional view for describing a second modification example of the semiconductor device manufacturing method according to the present embodiment.

FIG. 10 is a cross-sectional view for describing a third modification example of the semiconductor device manufacturing method according to the present embodiment.

### DESCRIPTION OF EMBODIMENTS

Hereinafter, an embodiment of the present disclosure will be described in detail with reference to the drawings. In the following description, the same or equivalent parts are denoted by the same reference numerals, and repeated descriptions thereof will be omitted. It is assumed that the positional relationship such as up, down, left, and right is based on the positional relationship shown in the drawings unless otherwise specified. The dimensional ratio of each drawing is not limited to the ratio shown in the drawing.

In this specification, the term “layer” includes not only a structure having a shape formed on the entire surface but also a structure having a shape partially formed when observed as a plan view. In this specification, the term “process/step” includes not only an independent process/step but also a step whose intended action is achieved even if the process/step cannot be clearly distinguished from other processes/steps. The numerical range indicated by using “to” indicates a range including the numerical values before and after “to” as the minimum and maximum values, respectively.

### Configuration of Semiconductor Device

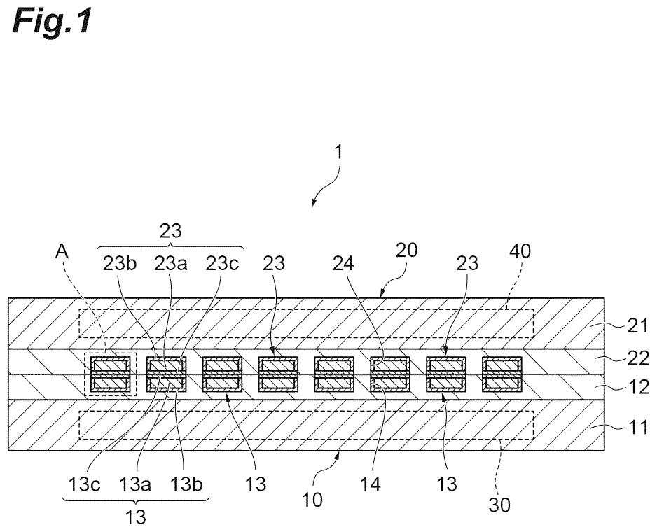

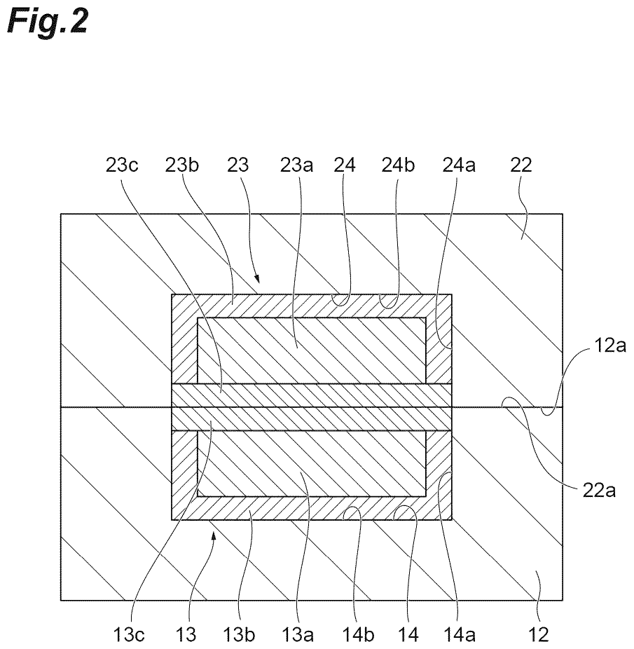

FIG. 1 is a cross-sectional view showing an example of a semiconductor device manufactured by using a method according to an embodiment of the present disclosure. FIG. 2 is an enlarged cross-sectional view showing a bonding portion A between electrodes in the semiconductor device shown in FIG. 1. A semiconductor device 1 is, for example, an example of a semiconductor package, and includes a first substrate 10 and a second substrate 20 as shown in FIGS. 1 and 2. In the semiconductor device 1, the first substrate 10 and the second substrate 20 are bonded to each other. The first substrate 10 may include a semiconductor chip 30 (semiconductor element), and the second substrate 20 may include a semiconductor chip 40 (semiconductor element). The semiconductor chip 30 may be arranged on a surface (lower surface in FIG. 1) of the first substrate 10 opposite to the second substrate 20. The semiconductor chip 40 may be arranged on a surface (upper surface in FIG. 1) of the second substrate 20 opposite to the first substrate 10. The semiconductor chips 30 and 40 are, for example, semiconductor chips such as Large Scale Integrated Circuit (LSI) chips, Complementary Metal Oxide Semiconductor (CMOS) sensors, and memories. The semiconductor chips 30 and 40 may be other types of semiconductor chips.

The first substrate 10 includes a first support substrate 11, a first insulating film 12, and a plurality of first electrodes 13. The first insulating film 12 is provided on the first support substrate 11. Each of the first electrodes 13 is provided in a first recess 14 formed in the first insulating film 12, and is formed so as to be exposed from a first surface 12a of the first insulating film 12.

The first support substrate 11 is not particularly limited, but may be, for example, a silicon plate, a glass plate, an SUS plate, a substrate containing glass cloth, or a sealing resin containing a semiconductor element. The first support substrate 11 is preferably a substrate having high rigidity. The thickness of the first support substrate 11 is preferably in the range of, for example, 0.2 to 2.0 mm. By setting the thickness to 0.2 mm or more, it is possible to improve the handleability of the first support substrate 11. By setting the thickness to 2.0 mm or less, it is possible to reduce material costs and to make the semiconductor device 1 thin. The shape of the first support substrate 11 in plan view may be either a wafer shape (disk shape) or a panel shape (rectangular shape). The size of the first support substrate 11 is not particularly limited, but the first support substrate 11 may have a wafer shape with a diameter of 200 mm, 300 mm, or 450 mm or may be a rectangular panel with each side of 300 to 700 mm, for example. The semiconductor chip 30 may be provided inside the first support substrate 11 or on a surface (lower surface in FIG. 1) of the first support substrate 11 opposite to the second substrate 20.

The first insulating film 12 is formed of an organic insulating material. The first insulating film 12 may partially contain an inorganic insulating material. The organic insulating material that forms the first insulating film 12 is, for example, a photosensitive organic insulating material or a thermosetting organic insulating material. The inorganic insulating material that forms the first insulating film 12 is, for example, a silicon-containing material such as silicon nitride (SiN), silicon dioxide (SiO₂), or silicon oxynitride (SiON). The organic insulating material that forms the first insulating film 12 may be, for example, polyimide, a polyimide precursor, polyamide-imide, benzocyclobutene (BCB), polybenzoxazole (PBO), or a PBO precursor. Since these materials are in a liquid state or soluble in a solvent, the insulating film can be easily manufactured by, for example, spin coating. Therefore, a thin film can be easily formed. Since these materials have high heat resistance, these materials can also withstand high temperatures when bonding the first substrate 10 and the second substrate 20 to each other. Therefore, bonding between the first substrate 10 and the second substrate 20 can be performed more reliably. The organic insulating material that forms the first insulating film 12 may be a liquid or film-shaped material, and is preferably a film-shaped material from the viewpoint of film thickness uniformity and cost. The first insulating film 12 may contain fillers in the organic insulating material, and the average particle size of the fillers contained in the insulating material is preferably 500 nm or less. By containing such fillers, a fine trench structure can be easily formed in the first insulating film 12. The first insulating film 12 may not contain fillers. The particle size of the fillers can be measured by using a laser diffraction type particle size distribution measurement method.

When the first insulating film 12 is formed by laminating a film-shaped organic insulating material onto the first support substrate 11, it is preferable that the lamination is performed in a low-temperature process. Therefore, it is preferable that the first insulating film 12 is a photosensitive organic insulating film that can be laminated at 40 to 120° C. By setting the laminable temperature of the photosensitive insulating film used for the first insulating film 12 to 40° C. or higher, it is possible to reduce the tackiness at room temperature so that the first insulating film 12 can be easily handled. By setting the laminable temperature of the photosensitive insulating film used for the first insulating film 12 to 120° C. or lower, it is possible to reduce the warpage of the photosensitive insulating film after lamination. The thermal expansion coefficient after curing of the organic insulating material used for the first insulating film 12 is preferably 80 ppm/° C. or less from the viewpoint of preventing warpage, and more preferably 70 ppm/° C. or less from the viewpoint of obtaining high reliability. The thermal expansion coefficient after curing of the insulating material used for the first insulating film 12 is preferably 20 ppm/° C. or more from the viewpoint of stress reduction and acquisition of highly precise patterns.

The thickness of the first insulating film 12 is preferably 10 μm or less, more preferably 5 μm or less, and even more preferably 3 μm or less. By setting the thickness of the first insulating film 12 to such a thickness, the first recess 14 formed in the first insulating film 12 can be made finer. From the viewpoint of ensuring electrical reliability, the thickness of the first insulating film 12 is preferably 1 μm or more.

The first electrode 13 is an electrode formed in the first insulating film 12, and has a first electrode body 13a, a first barrier metal 13b, and a second barrier metal 13c. The first electrode 13 may be a terminal electrode such as a bump, or may be a wiring electrode. The first electrode body 13a is provided in the first recess 14 formed in the first insulating film 12, and is formed of, for example, a highly conductive material such as copper, aluminium, or silver. The first barrier metal 13b is provided on an inner surface 14a and a bottom surface 14b of the first recess 14, and covers the side and bottom surfaces of the first electrode body 13a. The thickness of the first barrier metal 13b is in the range of 0.1 to 0.8 μm, for example. The bonding strength between the first insulating film 12 and the first barrier metal 13b is 30 MPa or more. The bonding strength between the first insulating film 12 and the first barrier metal 13b is preferably 40 MPa or more, and more preferably 50 MPa or more. The second barrier metal 13c covers the surface of the first electrode body 13a on the opening side of the first recess 14. The thickness of the second barrier metal 13c is in the range of 0.1 to 0.8 μm, and is 1 μm or less before being bonded to the second electrode, for example. The first electrode body 13a is entirely covered with the first barrier metal 13b and the second barrier metal 13c.

The first barrier metal 13b and the second barrier metal 13c are parts for preventing the first electrode body 13a, which is formed of a material that is easily ionized, from dissolving into the resin, and are formed of a conductive material having a low ionization tendency. The first barrier metal 13b and the second barrier metal 13c contain at least one selected from, for example, titanium, nickel, palladium, chromium, tantalum, tungsten, cobalt, and gold. The first barrier metal 13b and the second barrier metal 13c are preferably plated films (for example, electroless plated films), for example, nickel-plated films, palladium-plated films, cobalt-plated films, gold-plated films, or alloy-plated films containing at least one of nickel, palladium, cobalt, and gold. From the viewpoint of improving the bonding strength with respect to the first insulating film 12, the first barrier metal 13b is preferably a titanium film, a nickel film, a chromium film, a tungsten film, or a cobalt film. From the viewpoints of adhesion to the first electrode body 13a and resistance to temperature cycles, the first barrier metal 13b and the second barrier metal 13c are preferably nickel-plated films or palladium-plated films. These materials are materials having a low ionization tendency, and are materials having a high barrier performance for preventing the dissolution of materials such as copper forming the first electrode body 13a. From the viewpoint of barrier performance, it is preferable that the first barrier metal 13b and the second barrier metal 13c contain at least one selected from nickel, cobalt, and tungsten.

The second substrate 20 includes a second support substrate 21, a second insulating film 22, and a plurality of second electrodes 23. The second insulating film 22 is provided on the second support substrate 21. Each of the second electrodes 23 is provided in a second recess 24 formed in the second insulating film 22, and is formed so as to be exposed from a second surface 22a of the second insulating film 22. The second substrate 20 may have a similar configuration to the first substrate 10. The configuration of the second support substrate 21 may be similar to the configuration of the first support substrate 11. The configuration of the second insulating film 22 may be similar to the configuration of the first insulating film 12, and the second insulating film 22 is formed of an organic insulating material. The second insulating film 22 may partially contain an inorganic insulating material. Since the configuration of the second substrate 20 corresponds to the configuration of the first substrate 10, a description of the configurations of the second support substrate 21 and the second insulating film 22 will be omitted.

The second electrode 23 has a configuration similar to that of the first electrode 13, and includes a second electrode body 23a, a third barrier metal 23b, and a fourth barrier metal 23c. The second electrode 23 is an electrode that is bonded to the first electrode 13. Similarly to the first electrode 13, the second electrode 23 may be a terminal electrode, such as a bump, or may be a wiring electrode. The second electrode body 23a is provided in the second recess 24 formed in the second insulating film 22, and is formed of, for example, a highly conductive material such as copper, aluminium, or silver. The third barrier metal 23b is provided on an inner surface 24a and a bottom surface 24b of the second recess 24, and covers the side and bottom surfaces of the second electrode body 23a. The thickness of the third barrier metal 23b is in the range of 0.1 to 0.8 μm, for example. The bonding strength between the second insulating film 22 and the third barrier metal 23b is 30 MPa or more. The bonding strength between the second insulating film 22 and the third barrier metal 23b is preferably 40 MPa or more, and more preferably 50 MPa or more. The fourth barrier metal 23c covers the surface of the second electrode body 23a on the opening side of the second recess 24. The thickness of the fourth barrier metal 23c is in the range of 0.1 to 0.8 μm, and is 1 μm or less before being bonded to the first electrode 13, for example. The second electrode body 23a is entirely covered with the third barrier metal 23b and the fourth barrier metal 23c.

The third barrier metal 23b and the fourth barrier metal 23c are parts for preventing the second electrode body 23a, which is formed of a material that is easily ionized, from dissolving into the resin, and are formed of a conductive material having a low ionization tendency similarly to the first barrier metal 13b and the second barrier metal 13c. The third barrier metal 23b and the fourth barrier metal 23c contain at least one selected from, for example, titanium, nickel, palladium, chromium, tantalum, tungsten, cobalt, and gold. The third barrier metal 23b and the fourth barrier metal 23c are preferably plated films (for example, electroless plated films), for example, nickel-plated films, palladium-plated films, cobalt-plated films, gold-plated films, or alloy-plated films containing at least one of nickel, palladium, cobalt, and gold. From the viewpoint of improving the bonding strength with respect to the second insulating film 22, the third barrier metal 23b is preferably a titanium film, a nickel film, a chromium film, a tungsten film, or a cobalt film. From the viewpoints of adhesion to the second electrode body 23a and resistance to temperature cycles, the third barrier metal 23b and the fourth barrier metal 23c are preferably nickel-plated films or palladium-plated films. These materials are materials having a low ionization tendency, and are materials having a high barrier performance for preventing the dissolution of materials such as copper forming the second electrode body 23a. From the viewpoint of barrier performance, the third barrier metal 23b and the fourth barrier metal 23c preferably contain at least one selected from nickel, cobalt, and tungsten. In the semiconductor device 1, the second barrier metal 13c of the first electrode 13 and the fourth barrier metal 23c of the second electrode 23 are bonded to each other.

### Method for Manufacturing Semiconductor Device

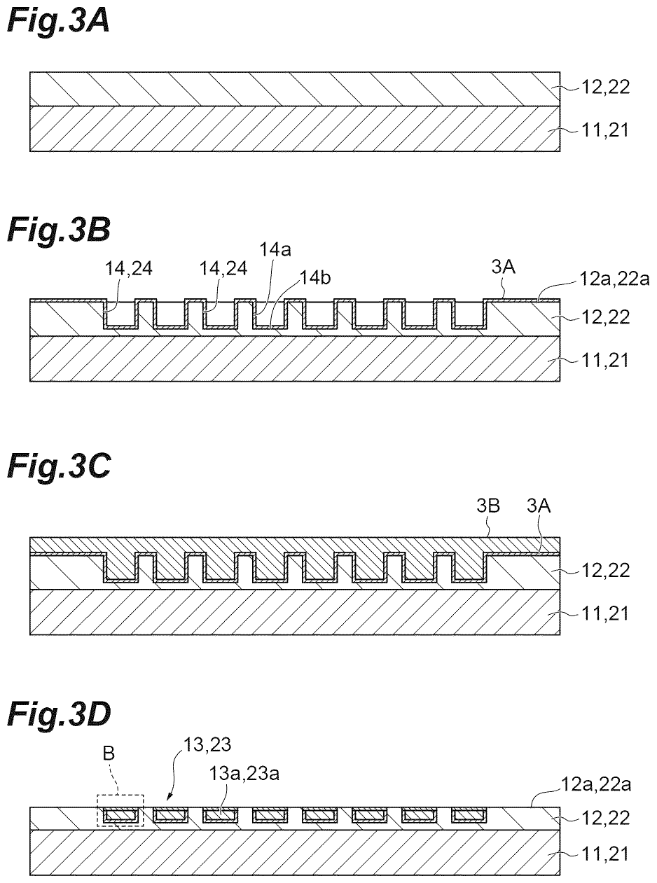

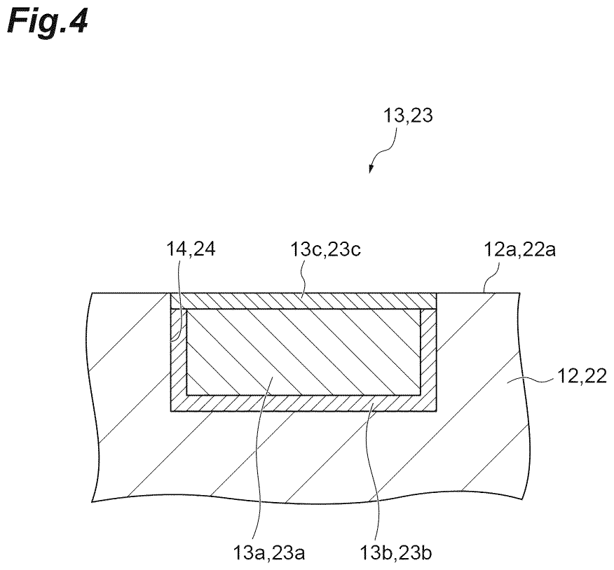

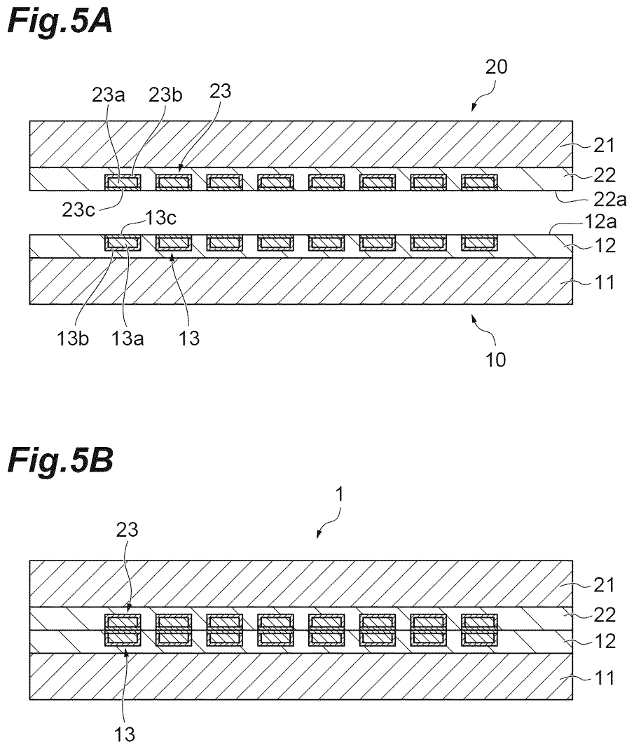

Next, a method for manufacturing the semiconductor device 1 will be described with reference to FIGS. 3A to 3D to FIGS. 5A and 5B. FIGS. 3A to 3D are cross-sectional views for describing a method for manufacturing the semiconductor device 1, and shows an example of a process of manufacturing each of the first substrate 10 and the second substrate 20. FIG. 4 is an enlarged cross-sectional view showing a region B shown in FIG. 3D. FIGS. 5A and 5B are cross-sectional views for describing a method for manufacturing the semiconductor device 1, and shows an example of a process of bonding the first substrate 10 and the second substrate 20 to each other, subsequent to the process in FIGS. 3A to 3D.

The semiconductor device 1 can be manufactured, for example, through the following processes (a) to (d).
(a) A process of preparing a first substrate having a first support substrate, a first insulating film provided on the first support substrate, and a first electrode provided in a first recess of the first insulating film and exposed from a first surface side of the first insulating film.
(b) A process of preparing a second substrate having a second support substrate, a second insulating film provided on the second support substrate, and a second electrode provided in a second recess of the second insulating film and exposed from a second surface side of the second insulating film.
(c) A process of bonding the first insulating film of the first substrate and the second insulating film of the second substrate to each other.
(d) A process of bonding the first electrode of the first substrate and the second electrode of the second substrate to each other.

The process (a) of preparing the first substrate includes the following processes.
(a1) A process of forming the first insulating film on the first support substrate.
(a2) A process of forming at least the one first recess in the first insulating film.
(a3) A process of forming the first barrier metal on the inner surface and the bottom surface of the first recess.
(a4) A process of forming the first electrode body in a region surrounded by the first barrier metal within the first recess.
(a5) A process of forming a second barrier metal on the surface of the first electrode body.
   In addition, the process (b) of preparing the second substrate includes the following processes.
(b1) A process of forming the second insulating film on the second support substrate.
(b2) A process of forming at least the one second recess in the second insulating film.
(b3) A process of forming the third barrier metal on the inner surface and the bottom surface of the second recess.
(b4) A process of forming the second electrode body in a region surrounded by the third barrier metal within the second recess.
(b5) A process of forming a fourth barrier metal on the surface of the second electrode body.

### Process (a)

A method for manufacturing (preparing) the first substrate 10 will be described. To manufacture the first substrate 10, first, the first support substrate 11 is prepared. The first support substrate 11 is a substrate having a thickness of, for example, 0.2 to 2.0 mm, and is a wafer-shaped or panel-shaped substrate. The first support substrate 11 may have other configurations. Thereafter, as shown in FIG. 3A, the first insulating film 12 is formed on the first support substrate 11. For example, when the first insulating film 12 is formed from a photosensitive insulating film, the first insulating film 12 is formed by laminating the photosensitive insulating film on the first support substrate 11. As materials of the insulating film, the materials described above can be used. The lamination temperature may be, for example, 40 to 120° C. The photosensitive insulating film used herein may contain a thermosetting organic insulating material. The method of forming the first insulating film 12 is not limited to this, and the first insulating film 12 may be formed by using other methods. For example, when the first insulating film 12 is formed of a liquid organic insulating material, the first insulating film 12 may be formed by applying the insulating material onto the first support substrate 11 and then rotating the first support substrate 11. The thickness of the first insulating film 12 formed on the first support substrate 11 is, for example, 10 μm or less, preferably 5 μm or less, and more preferably 3 μm or less. The thickness of the first insulating film 12 may be 1 μm or more. The first insulating film 12 may be formed of an inorganic material.

Subsequently, as shown in FIG. 3B, a plurality of first recesses 14 are formed in the first insulating film 12. The first recess 14 can be formed by using, for example, laser ablation, photolithography, and imprinting. When a photolithography process is used, it is possible to manufacture the fine first recess 14 at low cost. When forming the recess using the photolithography process, it is preferable to use a film-shaped photosensitive organic insulating material for the first insulating film 12. As a method for exposing a photosensitive organic insulating material, a normal projection exposure method, a contact exposure method, a direct writing exposure method, and the like can be used. As a development method, a method of development using an alkaline aqueous solution of sodium carbonate or TMAH can be used. After forming the first recess 14, the insulating material (thermosetting material) forming the first insulating film 12 may be further heated and cured. The heating temperature in this case may be, for example, 100 to 200° C., and the heating time may be, for example, 30 minutes to 3 hours. The first recess 14 formed by the above method has an opening diameter or an opening width of 5 μm to 50 μm.

Subsequently, once a plurality of first recesses 14 are formed in the first insulating film 12, the first barrier metal 13b is formed on the inner surface 14a and the bottom surface 14b of each of the first recesses 14. In the process of forming the first barrier metal 13b, as shown in FIG. 3B, a conductive material 3A forming the first barrier metal 13b is formed on the inner surface 14a and the bottom surface 14b of the first recess 14 and the first surface 12a of the first insulating film 12 by plating (electroless plating) or the like. At this time, a first barrier metal is formed so that the bonding strength between the first insulating film 12 and the first barrier metal 13b is 30 MPa or more. The bonding strength between the first insulating film 12 and the first barrier metal 13b may be 40 MPa or more, or may be 50 MPa or more. The conductive material 3A forming the first barrier metal 13b contains, for example, at least one selected from titanium, nickel, palladium, chromium, tantalum, tungsten, cobalt, and gold. Since the first barrier metal 13b also functions as a seed layer for forming the first electrode body 13a described later, the first barrier metal 13b may be any one of titanium, copper, nickel, nickel alloy (NiP, NiB, CoNiP), cobalt, and tungsten alloy (Taw). These materials are applied, for example, by electroless plating.

Here, the bonding strength when a barrier film is provided on an organic material film will be described. When copper is provided directly on an organic material film without a barrier film therebetween, the copper oxidizes to be peeled off from the organic material film with the elapse of time. However, when a copper electrode is provided on the organic material film with a barrier film interposed therebetween, such peeling can be prevented. For example, the present inventors used a photosensitive insulating material (manufactured by Resonac Corporation, product name AH-3000) as an organic material film and used a NiB film (manufactured by JCU CORPORATION, product name) as a barrier film, and formed a barrier film on the organic material film by electroless nickel boron plating. The thickness of the barrier film formed was 100 nm. The barrier film was formed by electroless plating. A peel strength test between the barrier film and the organic material film was performed on this test piece. The peel strength at this time was, for example, 40 MPa. That is, it is confirmed that the bonding strength between the first insulating film 12 and the first barrier metal 13b can be increased to 30 MPa or more or 40 MPa or more by using the above-described method. By changing the type of organic insulating film or the type of barrier film used, it is possible to further increase the bonding strength between the first insulating film 12 and the first barrier metal 13b to 50 MPa or more. The above can also be applied to the bonding strength between the second insulating film 22 and the third barrier metal 23b, which will be described later.

Subsequently, once the first barrier metal 13b (conductive material 3A) is formed, the first electrode body 13a is formed in the first recess 14 in a region surrounded by the first barrier metal 13b. In the process of forming the first electrode body 13a, as shown in FIG. 3C, a conductive material 3B forming the first electrode body 13a is formed on the conductive material 3A, which is formed inside the first recess 14 and on the first insulating film 12, by electrolytic plating or the like. The conductive material 3B forming the first electrode body 13a contains, for example, at least one selected from copper, aluminium, and silver. The first electrode body 13a (conductive material 3B) is formed by electrolytic plating using the first barrier metal 13b (conductive material 3A) functioning as a seed layer as a power supply layer. When forming the first electrode body 13a, a conductive material such as copper is deposited on the first insulating film 12 and on the first barrier metal 13b in the first recess 14 so as to fill the first recess 14.

Subsequently, once the conductive material 3B forming the first electrode body 13a is formed, the conductive material 3A of the first barrier metal 13b and the conductive material 3B of the first electrode body 13a are ground to remove unnecessary portions, thereby forming the first barrier metal 13b and the first electrode body 13a having a predetermined thickness. During this grinding, the first insulating film 12 may be ground together with the conductive material 3A and the conductive material 3B to have a predetermined thickness.

Subsequently, once the first electrode body 13a and the first barrier metal 13b are formed, the first surface 12a of the first insulating film 12 is polished. For this polishing, a method such as a grinder for electronic material processing or Chemical Mechanical Polishing (CMP) can be used. By this polishing, the surface roughness of the first surface 12a of the first insulating film 12 becomes 0.1 μm or less. The surface roughness used herein is an arithmetic mean roughness Ra measured using a laser microscope at a magnification of 20 times, and is the arithmetic mean roughness Ra specified in JIS B 0601 2001. This polishing may be performed under conditions in which the surface of the first electrode body 13a and the first surface 12a of the first insulating film 12 are flush with each other, or this polishing may be performed under conditions in which the surface of the first electrode body 13a protrudes from the first surface 12a of the first insulating film 12, or this polishing may be performed under conditions in which the surface of the first electrode body 13a is recessed inward from the first surface 12a of the first insulating film 12. As an example, the first insulating film 12 is polished so that the surface of the first electrode body 13a is recessed slightly inward from the first surface 12a of the first insulating film 12. Such conditions can be controlled by appropriately adjusting the polishing liquid and polishing conditions used in CMP.

Subsequently, once the surfaces of the first insulating film 12 and the first electrode body 13a are polished, the surface of the first electrode body 13a is subjected to surface modification by at least one method of ultraviolet irradiation, electron beam irradiation, ozone water treatment, corona discharge treatment, and plasma treatment. This surface modification is a pretreatment for forming the second barrier metal 13c, which will be described later.

Subsequently, as shown in FIG. 3D, the second barrier metal 13c is formed on the surface of the first electrode body 13a. In this process, after the above-described processes of polishing the conductive material and pretreating the surface of the first electrode body, a second barrier metal is formed so as to cover the surface of the first electrode body 13a. The second barrier metal 13c is formed on the first electrode body 13a by, for example, electroless plating. The second barrier metal 13c is formed of a material containing at least one selected from, for example, titanium, nickel, palladium, chromium, tantalum, tungsten, cobalt, and gold. The second barrier metal 13c is formed of a material having a low ionization tendency. When forming the second barrier metal 13c by electroless plating, a material may be formed so as to cover the first surface 12a of the first insulating film 12, as in the formation of the first barrier metal 13b. In this case, an excess material is ground or polished in the same manner as described above. Through the processes described above, the first substrate 10 is prepared.

### Process (b)

A method for manufacturing the second substrate 20 is similar to the method for manufacturing the first substrate 10. Therefore, a detailed description will be omitted, and the second substrate 20 is manufactured through the processes described above shown in FIGS. 3A to 3D. In the examples shown in FIGS. 3A to 3D and FIGS. 5A and 5B, the second substrate 20 has a similar configuration to the first substrate 10 but does not need to have completely the same configuration as the first substrate 10, and the thickness or forming material of the second support substrate 21, the thickness or forming material of the second insulating film 22, the presence or absence of a semiconductor chip, and the like may be different from those in the first substrate 10.

### Process (c)

Then, once the preparation of the first substrate 10 and the second substrate 20 is completed, the first insulating film 12 of the first substrate 10 and the second insulating film 22 of the second substrate 20 are bonded to each other. In this process, as shown in FIG. 5A, at least one of the first substrate 10 and the second substrate 20 is aligned so that the first electrodes 13 of the first substrate 10 and the second electrodes 23 of the second substrate 20 correspond to each other. Both the first substrate 10 and the second substrate 20 may be aligned. For such alignment, an alignment mark or the like may be provided in at least one of the first substrate 10 and the second substrate 20.

In process (c), after removing organic substances or metal oxides adhering to the surfaces of the first substrate 10 and the second substrate 20, the second substrate 20 is aligned with the first substrate 10. Once the alignment is completed, the first insulating film 12 of the first substrate 10 and the second insulating film 22 of the second substrate 20 are bonded to each other as hybrid bonding. At this time, the first insulating film 12 of the first substrate 10 and the second insulating film 22 of the second substrate 20 may be uniformly heated and then bonded to each other. The temperature difference between the first substrate 10 and the second substrate 20 during bonding is preferably, for example, 10° C. or less. By such heat bonding at a uniform temperature, the first insulating film 12 is mechanically and firmly attached to the second insulating film 22. Since the heat bonding is performed at a uniform temperature, a misalignment at the bonding portion is unlikely to occur. Therefore, high-accuracy bonding can be performed. At the stage of bonding, the first electrodes 13 of the first substrate 10 and the second electrodes 23 of the second substrate 20 are spaced apart from each other and are not bonded to each other (however, aligned). The first substrate 10 and the second substrate 20 may be bonded to each other using other bonding methods, for example, room temperature bonding.

### Process (d)

Then, once the bonding between the first substrate 10 and the second substrate 20 is completed, a plurality of first electrodes 13 of the first substrate 10 and a plurality of second electrodes 23 of the second substrate 20 are bonded to each other, respectively. In process (d), as shown in FIG. 5B, once the bonding in process (c) is completed, a predetermined heat or pressure or both are applied to bond the first electrodes 13 of the first substrate 10 and the second electrodes 23 of the second substrate 20 to each other, respectively, as hybrid bonding. When the first electrodes 13 and the second electrodes 23 are formed of, for example, copper, the annealing temperature in process (d) is preferably 150° C. to 400° C., and more preferably 200° C. to 300° C. By such a bonding process, the first electrode 13 and the second electrode 23 corresponding thereto are bonded to each other to form an electrode-bonded part, so that the first electrode 13 and the second electrode 23 are bonded to each other mechanically and electrically firmly. The electrode bonding in process (d) may be performed after the bonding in process (c), or may be performed simultaneously with the bonding in process (c).

Through the processes described above, the semiconductor device 1 shown in FIG. 1 is manufactured.

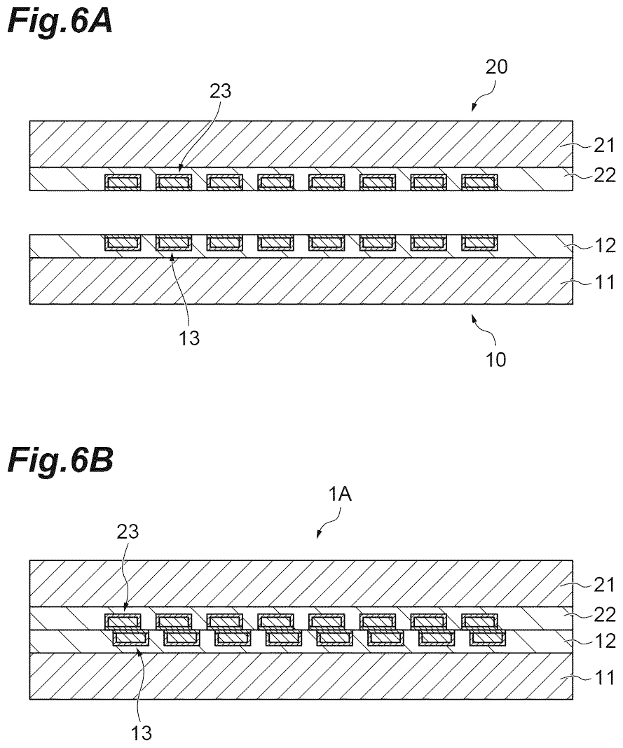

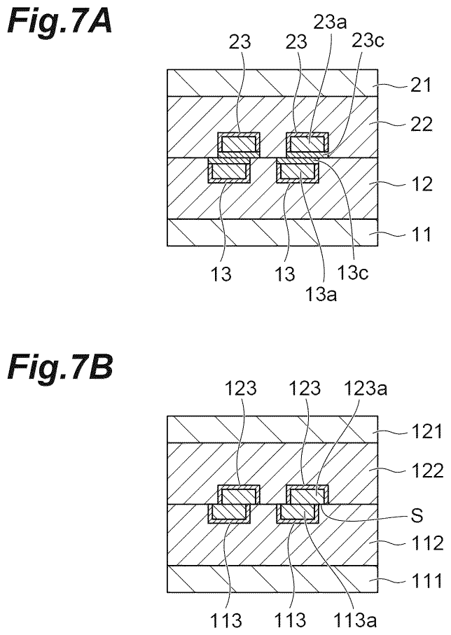

Here, with reference to FIGS. 6A and 6B and FIGS. 7A and 7B, the function and effect of the semiconductor device manufacturing method according to the present embodiment will be described by comparing the semiconductor device manufacturing method according to the present embodiment with a semiconductor device manufacturing method according to a comparative example. FIGS. 6A and 6B are cross-sectional views showing an example in which a misalignment occurs when the first substrate 10 and the second substrate 20 are bonded to each other to bond the first electrodes 13 and the second electrodes 23 to each other. FIG. 7A is a cross-sectional view showing a case where a misalignment occurs at bonding portions of a semiconductor device 1A manufactured by using the method according to the present embodiment, and FIG. 7B is a cross-sectional view showing a case where a misalignment occurs at bonding portions of a semiconductor device manufactured by using the method according to the comparative example. The manufacturing method according to the comparative example is different from the manufacturing method according to the embodiment in that metal caps corresponding to the second barrier metal 13c and the fourth barrier metal 23c are not provided on a first electrode 113 corresponding to the first electrode 13 and a second electrode 123 corresponding to the second electrode 23. The other processes and configurations are similar to those in the embodiment.

When such a misalignment occurs, as shown in FIG. 7B, in the semiconductor device manufacturing method according to the comparative example, due to misalignment S, a first electrode body 113a of the first electrode 113 is exposed on the side of a resin forming a second insulating layer 121. Similarly, a second electrode body 123a of the second electrode 123 is exposed on the side of a resin forming a first insulating layer 111. In this case, copper or the like forming the first electrode body 113a and the second electrode body 123a is dissolved, causing migration between the electrodes and the resin. This may result in, for example, a short circuit between the terminal electrodes.

On the other hand, in the method for manufacturing the semiconductor devices 1 and 1A and the semiconductor devices 1 and 1A according to the present embodiment, the surface of the first electrode body 13a of the first electrode 13 is covered with the second barrier metal 13c, and the entire first electrode body 13a is covered with the first barrier metal 13b and the second barrier metal 13c. Similarly, the surface of the second electrode body 23a of the second electrode 23 is covered with the fourth barrier metal 23c, and the entire second electrode body 23a is covered with the third barrier metal 23b and the fourth barrier metal 23c. In this case, the dissolution of the first electrode body 13a and the second electrode body 23a, which are often formed of a material that dissolves easily, such as copper, is prevented by the first barrier metal 13b, the second barrier metal 13c, the third barrier metal 23b, and the fourth barrier metal 23c. Therefore, even if a misalignment occurs between the first electrode 13 and the second electrode 23 at any stage, migration at the interface between the first electrode 13 and the first insulating film 12 can be prevented, and migration at the interface between the second electrode 23 and the second insulating film 22 can be prevented.

The bond between an electrode material, such as copper, and a resin forming an insulating film can be weak to peel off. However, in the method for manufacturing the semiconductor devices 1 and 1A according to the present embodiment, the first barrier metal 13b is provided on the inner surface 14a and the bottom surface 14b of the first recess 14 of the first insulating film 12 to cover a part of the first electrode body 13a, and the bonding strength between the first insulating film 12 and the first barrier metal 13b is 30 MPa or more, so that it is possible to prevent such peeling. Similarly, the third barrier metal 23b is provided on the inner surface 24a and the bottom surface 24b of the second recess 24 of the second insulating film 22 to cover a part of the second electrode body 23a, and the bonding strength between the second insulating film 22 and the third barrier metal 23b is 30 MPa or more, so that it is possible to prevent such peeling.

In the method for manufacturing the semiconductor devices 1 and 1A according to the present embodiment, the first insulating film 12 and the second insulating film 22 include an organic insulating film. In this case, an organic material, which is a relatively soft material, can absorb foreign matter (debris) adhering to the surfaces of the first substrate 10 and the second substrate 20 into the insulating film, thereby reducing poor connections between the first substrate 10 and the second substrate 20. The organic insulating material contained in the insulating film may be polyimide, a polyimide precursor, polyamide-imide, benzocyclobutene (BCB), polybenzoxazole (PBO), or a PBO precursor. Since these materials are in a liquid state or soluble in a solvent, the insulating film can be easily manufactured by, for example, spin coating. Therefore, a thin film can be easily formed. Since these materials have high heat resistance, these materials can withstand high temperatures when bonding the first substrate 10 and the second substrate 20 to each other. Therefore, bonding between the first substrate 10 and the second substrate 20 can be performed more reliably.

In the method for manufacturing the semiconductor devices 1 and 1A according to the present embodiment, the thicknesses of the second barrier metal 13c and the fourth barrier metal 23c before bonding the first electrode 13 and the second electrode 23 to each other may be 1 μm or less. In this case, the terminal electrodes can be made finer more reliably.

In the method for manufacturing the semiconductor devices 1 and 1A according to the present embodiment, when bonding the first electrode 13 and the second electrode 23 to each other, the second barrier metal 13c and the fourth barrier metal 23c are bonded to each other. Therefore, even if a misalignment occurs between the first electrode 13 and the second electrode 23, a part of at least one of the second barrier metal 13c and the fourth barrier metal 23c is bonded to the resin, thereby preventing the first electrode body 13a and the second electrode body 23a from being bonded to the resin. This makes it possible to more reliably prevent migration at the interface between the first electrode 13 and the first insulating film 12 and the interface between the second electrode 23 and the second insulating film 22.

In the method for manufacturing the semiconductor devices 1 and 1A according to the present embodiment, the second barrier metal 13c and the fourth barrier metal 23c may be formed to contain at least one selected from titanium, nickel, palladium, chromium, tantalum, tungsten, cobalt, and gold. Since the second barrier metal 13c and the fourth barrier metal 23c contain such a material with high barrier performance, migration at the interface between the first electrode 13 and the first insulating film 12 and the interface between the second electrode 23 and the second insulating film 22 can be more reliably prevented.

In the above manufacturing method, the case where the first insulating film 12 and the second insulating film 22 include an organic insulating film has been described. However, without being limited thereto, in the semiconductor device manufacturing method according to the present embodiment, the first insulating film 12 and the second insulating film 22 may further include an inorganic insulating film. When the insulating film contains an inorganic insulating film, the recess for the terminal electrode is easy to be finer. Therefore, it is possible to manufacture the semiconductor devices 1 and 1A having finer wiring. Since it is easy to strengthen the bonding between inorganic materials, it is possible to improve the connection reliability of the semiconductor device by increasing the bonding strength between the first substrate 10 and the second substrate 20.

In the method for manufacturing the semiconductor devices 1 and 1A according to the present embodiment, the first insulating film 12 and the second insulating film 22 may be polished by CMP or the like, and the surface roughness of each of the polished first insulating film 12 and second insulating film 22 may be 0.1 μm or less. Therefore, it is possible to increase the bonding strength when the first insulating film 12 and the second insulating film 22 are bonded to each other.

In the method for manufacturing the semiconductor devices 1 and 1A according to the present embodiment, before the process of forming the second barrier metal 13c, the surface of the first electrode body 13a may be subjected to surface modification by using at least one method of ultraviolet irradiation, electron beam irradiation, ozone water treatment, corona discharge treatment, and plasma treatment. Therefore, since it is possible to improve the bonding strength of the second barrier metal 13c with respect to the first electrode body 13a, it is possible to prevent migration by preventing the peeling of the second barrier metal 13c and the like. Similarly, before the process of forming the fourth barrier metal 23c, the surface of the second electrode body 23a may be subjected to surface modification by using at least one method of ultraviolet irradiation, electron beam irradiation, ozone water treatment, corona discharge treatment, and plasma treatment. Therefore, since it is possible to improve the bonding strength of the fourth barrier metal 23c with respect to the second electrode body 23a, it is possible to prevent migration by preventing the peeling of the fourth barrier metal 23c and the like.

### First Modification Example

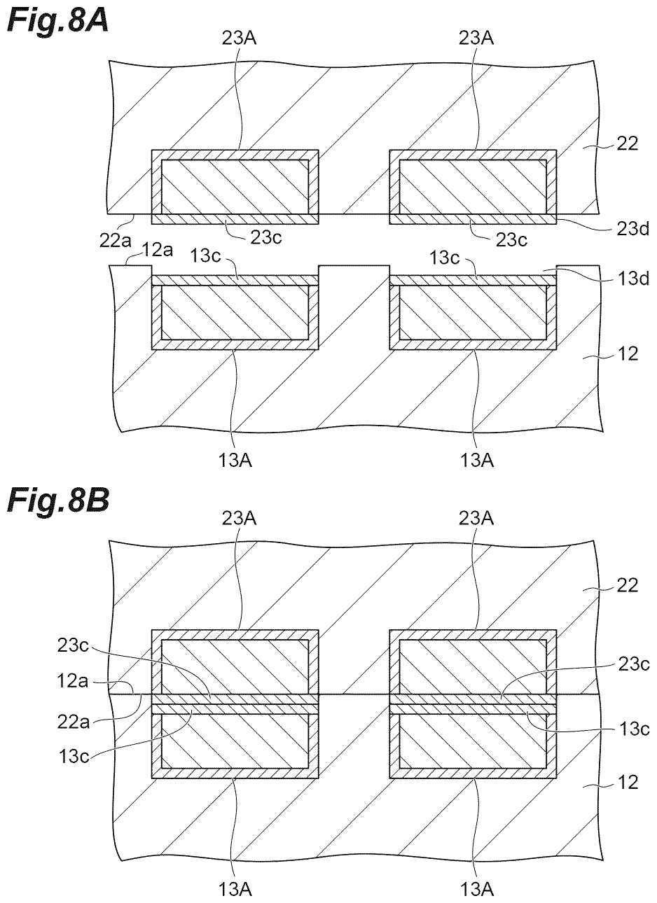

Here, a first modification example of the semiconductor device manufacturing method according to the present embodiment will be described with reference to FIGS. 8A and 8B. FIGS. 8A and 8B are cross-sectional views for describing the first modification example of the semiconductor device manufacturing method according to the present embodiment. As shown in FIG. 8A, in the semiconductor device manufacturing method according to the first modification example, in process (a), a first electrode 13A is formed so that the surface of the second barrier metal 13c is recessed inward from the first surface 12a of the first insulating film 12. Such a recessed region 13d can be formed by controlling at least one of the depth of the first recess 14, the thickness of the first barrier metal 13b, the amount of conductive material forming the first electrode body 13a or the position on the surface of the first electrode body 13a, the grinding or polishing conditions for the first insulating film 12 and the first electrode body 13a, the thickness or amount of the second barrier metal 13c to be arranged, and the like.

In the semiconductor device manufacturing method according to the first modification example, in process (b), a second electrode 23A is formed so that the surface of the fourth barrier metal 23c protrudes outward from the second surface 22a of the second insulating film 22. Such a protruding part 23d can be formed by controlling at least one of the depth of the second recess 24, the thickness of the third barrier metal 23b, the amount of conductive material forming the second electrode body 23a or the position on the surface of the second electrode body 23a, the grinding or polishing conditions for the second insulating film 22 and the second electrode body 23a, the thickness or amount of the fourth barrier metal 23c to be arranged, and the like.

Subsequently, in the manufacturing method according to the first modification example, as shown in FIG. 8B, when bonding the first insulating film 12 and the second insulating film 22 to each other in process (c), the protruding part 23d of the fourth barrier metal 23c is fitted into the recessed region 13d of the second barrier metal 13c. Due to such an uneven configuration, in the manufacturing method according to the first modification example, the first substrate 10 and the second substrate 20 are more reliably aligned to prevent misalignment. Thereafter, in process (d), the first electrode 13A and the second electrode 23A are bonded to each other. In the semiconductor device manufacturing method according to the first modification example, in addition to the effect of preventing the dissolution of copper and the like using the second barrier metal 13c and the fourth barrier metal 23c, it is possible to prevent misalignment during bonding due to such an alignment structure. Therefore, it is possible to further prevent migration at the interface between the electrode and the insulating film.

### Second Modification Example

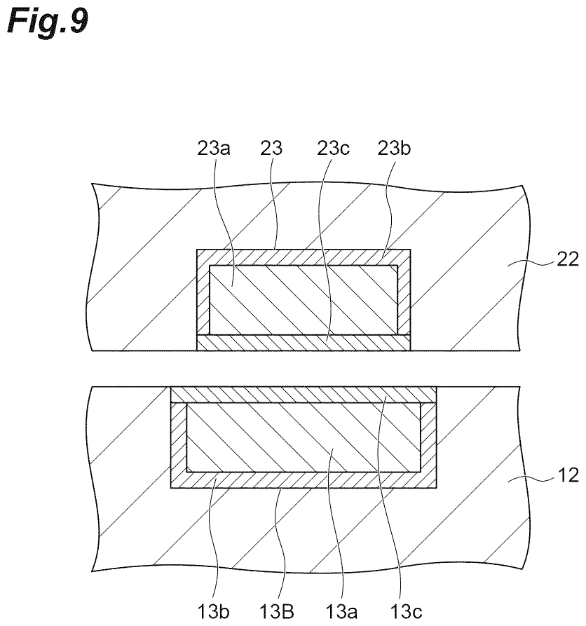

Next, a second modification example of the semiconductor device manufacturing method according to the present embodiment will be described with reference to FIG. 9. FIG. 9 is a cross-sectional view for describing the second modification example of the semiconductor device manufacturing method according to the present embodiment. In the above embodiment, an example has been described in which the first electrode 13 and the second electrode 23 have the same width, but the present disclosure is not limited thereto. For example, as shown in FIG. 9, the width of the first electrode 13B may be formed to be larger than the width of the second electrode 23. In this case, even if the second electrode 23 is slightly misaligned with respect to the first electrode 13B, the entire second electrode 23 can be bonded to the first electrode 13B. The width of the first electrode 13B may be, for example, more than 1.0 times and equal to or less than 3.0 times the width of the second electrode 23. In this case, even if a slight misalignment occurs, it is possible to prevent migration at the interface between the electrode and the insulating film.

### Third Modification Example

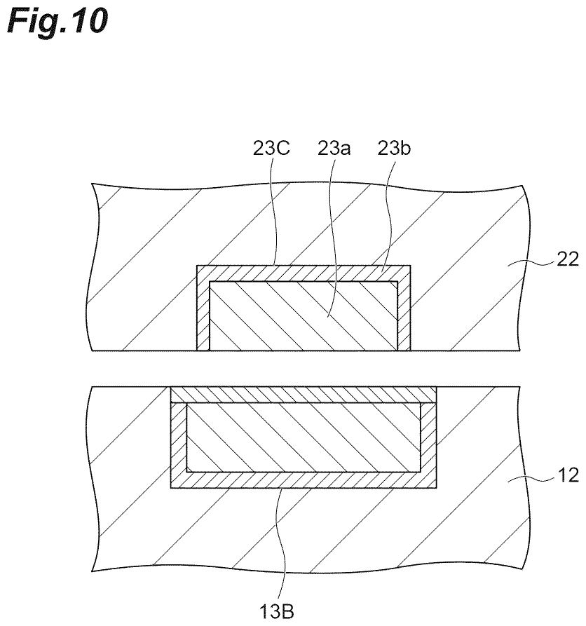

Next, a third modification example of the semiconductor device manufacturing method according to the present embodiment will be described with reference to FIG. 10. FIG. 10 is a cross-sectional view for describing the third modification example of the semiconductor device manufacturing method according to the present embodiment. In the third modification example, similarly to the second modification example, as shown in FIG. 10, the width of the first electrode 13B is formed to be larger than the width of the second electrode 23C. On the other hand, in this modification example, the first electrode 13B has the second barrier metal 13c, but the second electrode 23C does not have the fourth barrier metal 23c. In this case, even if the second electrode 23C is slightly misaligned with respect to the first electrode 13B, the entire second electrode 23C can be bonded to the first electrode 13B. Therefore, even if a slight misalignment occurs, it is possible to prevent migration at the interface between the electrode and the insulating film. By providing a barrier metal, which is a metal cap, on at least one side in this manner, it is possible to prevent migration.

While the embodiment of the present disclosure has been described above, the present invention is not limited to the embodiment described above, and can be appropriately changed without departing from the spirit of the present disclosure.

### REFERENCE SIGNS LIST

1, 1A: semiconductor device, 10: first substrate, 11: first support substrate, 12: first insulating film, 12a: first surface, 13, 13A, 13B: first electrode, 13a: first electrode body, 13b: first barrier metal, 13c: second barrier metal, 13d: recessed region, 14: first recess, 14a: inner surface, 14b: bottom surface, 20: second substrate, 21: second support substrate, 22: second insulating film, 22a: second surface, 23, 23A, 23C: second electrode, 23a: second electrode body, 23b: third barrier metal, 23c: fourth barrier metal, 23d: protruding part, 30, 40: semiconductor chip (semiconductor element).

1. A method for manufacturing a semiconductor device, comprising:
preparing a first substrate including a first support substrate, a first insulating film provided on the first support substrate, and a first electrode provided in a first recess of the first insulating film and exposed from a first surface side of the first insulating film;
preparing a second substrate including a second support substrate, a second insulating film provided on the second support substrate, and a second electrode provided in a second recess of the second insulating film and exposed from a second surface side of the second insulating film;
bonding the first insulating film of the first substrate and the second insulating film of the second substrate to each other; and
bonding the first electrode of the first substrate and the second electrode of the second substrate to each other,
wherein the first insulating film includes an organic insulating film, the first electrode includes a first electrode body provided in the first recess, a first barrier metal provided on at least one of an inner surface and a bottom surface of the first recess to cover a part of the first electrode body, and a second barrier metal covering a surface of the first electrode body on an opening side of the first recess, and
wherein a bonding strength between the first insulating film and the first barrier metal is 30 MPa or more.

2. The method for manufacturing a semiconductor device according to claim 1,
wherein the bonding strength between the first insulating film and the first barrier metal is 40 MPa or more.

3. The method for manufacturing a semiconductor device according to claim 1,
wherein the preparing of the first substrate includes:
forming the first insulating film on the first support substrate;
forming at least the one first recess in the first insulating film;
forming the first barrier metal on the inner surface and the bottom surface of the first recess;
forming the first electrode body in a region surrounded by the first barrier metal within the first recess; and
forming a second barrier metal on the surface of the first electrode body.

4. The method for manufacturing a semiconductor device according to claim 3,
wherein, in the forming of the first barrier metal, the first barrier metal is formed in the first recess of the first insulating film by electroless plating.

5. The method for manufacturing a semiconductor device according to claim 4,
wherein, in the forming of the first electrode body, the first electrode body is formed by electrolytic plating using the first barrier metal as a power supply layer.

6. The method for manufacturing a semiconductor device according to claim 3,
wherein, in the forming of the first electrode body, a conductive material is arranged on the first insulating film and the first barrier metal in the first recess so as to fill at least the first recess, and the arranged conductive material is ground to form the first electrode body.

7. The method for manufacturing a semiconductor device according to claim 6,
wherein, in the forming of the first electrode body, the first insulating film is polished after the conductive material is ground, and a surface roughness of the polished first insulating film is 0.1 μm or less.

8. The method for manufacturing a semiconductor device according to claim 6,
wherein, in the forming of the second barrier metal, the second barrier metal is formed so as to cover the surface of the first electrode body after the conductive material is ground.

9. The method for manufacturing a semiconductor device according to claim 3,
wherein the preparing of the first substrate includes modifying the surface of the first electrode body using at least one method of ultraviolet irradiation, electron beam irradiation, ozone water treatment, corona discharge treatment, and plasma treatment before the forming of the second barrier metal.

10. The method for manufacturing a semiconductor device according to claim 1,
wherein the first electrode body is entirely covered with the first barrier metal and the second barrier metal.

11. The method for manufacturing a semiconductor device according to claim 1,
wherein a thickness of the second barrier metal before bonding the first electrode and the second electrode to each other is 1 μm or less.

12. The method for manufacturing a semiconductor device according to claim 1,
wherein the second insulating film includes an organic insulating film, the second electrode includes a second electrode body provided in the second recess, a third barrier metal provided on at least one of an inner surface and a bottom surface of the second recess to cover a part of the second electrode body, and a fourth barrier metal covering a surface of the second electrode body on an opening side of the second recess, and
wherein a bonding strength between the second insulating film and the third barrier metal is 30 MPa or more.

13. The method for manufacturing a semiconductor device according to claim 12,
wherein the first electrode is formed so that a surface of the second barrier metal is recessed inward from the first surface of the first insulating film, and the second electrode is formed so that a surface of the fourth barrier metal protrudes outward from the second surface of the second insulating film, and
wherein, in the bonding of the first insulating film and the second insulating film to each other, a protruding part of the fourth barrier metal is fitted into a recessed region of the second barrier metal.

14. The method for manufacturing a semiconductor device according to claim 1,
wherein at least one semiconductor element is arranged within the first support substrate or on a surface of the first support substrate opposite to a surface on which the first insulating film is formed.

15. A semiconductor device, comprising:
a first substrate including a first support substrate, a first insulating film provided on the first support substrate, and a first electrode provided in a first recess of the first insulating film and exposed from a first surface side of the first insulating film; and
a second substrate including a second support substrate, a second insulating film provided on the second support substrate, and a second electrode provided in a second recess of the second insulating film and exposed from a second surface side of the second insulating film,
wherein the first insulating film includes an organic insulating film,
wherein the first insulating film and the second insulating film are bonded to each other, and the first electrode and the second electrode are bonded to each other, and
wherein the first electrode includes a first electrode body provided in the first recess, a first barrier metal provided on at least one of an inner surface and a bottom surface of the first recess to cover a part of the first electrode body, and a second barrier metal covering a surface of the first electrode body on an opening side of the first recess, and
wherein a bonding strength between the first insulating film and the first barrier metal is 30 MPa or more.

16. The semiconductor device according to claim 15,
wherein the second insulating film includes an organic insulating film, and
wherein the second electrode includes a second electrode body provided in the second recess, a third barrier metal provided on at least one of an inner surface and a bottom surface of the second recess to cover a part of the second electrode body, and a fourth barrier metal covering a surface of the second electrode body on an opening side of the second recess, and
wherein a bonding strength between the second insulating film and the third barrier metal is 30 MPa or more.
